(19) United States
(12) Patent Application Publication
(10) Pub. No.: US 2024/0379779 A1
(43) Pub. Date: Nov. 14, 2024

(54) CONDUCTIVITY-CONTROLLED POWER SEMICONDUCTOR DEVICE

(71) Applicant: BOARD OF REGENTS, THE UNIVERSITY OF TEXAS SYSTEM, Austin, TX (US)

(72) Inventor: Qin HUANG, Austin, TX (US)

(21) Appl. No.: 18/696,579

(22) PCT Filed: Sep. 29, 2022
(86) PCT No.: PCT/US2022/045209

§ 371 Date: Mar. 28, 2024

Related U.S. Application Data
(60) Provisional application No. 63/249,814, filed on Sep. 29, 2021.

(51) Int. Cl. H01L 29/40; H01L 29/16; H01L 29/20; H01L 29/732; H01L 29/78; H01L 29/861

(52) U.S. Cl. CPC H01L 29/402; H01L 29/1608; H01L 29/2003; H01L 29/732; H01L 29/7802; H01L 29/861

(57) ABSTRACT

Exemplary power semiconductor devices configured with one or more conductivity-controlled device regions and structures that can actively modulate, via an additional conductivity-controlled terminal, the conductivity characteristics of the power device. Through this active modulation and device structure, the conductivity and thus resistance of the power semiconductor device can be altered to substantially reduce losses (switching and conduction) of the device during operations. The exemplary conductivity-controlled power semiconductor devices (also referred to herein as “CCBT”) can provide a substantial energy saving as well as reduce the thermal regulation requirements for any power application using additional conductivity-controlled circuitries. The conductivity-controlled device regions and structures can be applied to silicon-based power electronics, wide-bandgap power electronics, and any other classes of materials for power electronic devices.

### RELATED APPLICATION

This PCT International Patent Application claims priority to, and the benefit of, U.S. Provisional Patent Application No. 63/249,814, filed Sep. 29, 2021, entitled “Conductivity-Controlled Power Semiconductor Device,” which is incorporated by reference herein in its entirety.

### BACKGROUND

Power semiconductor devices such as insulated-gate bipolar transistors (IGBTs), thyristors, metal-oxide-semiconductor field-effect transistors (MOSFETs), bipolar junction transistors (BJTs), and diodes are configured and optimized to operate in commutation mode (either on or off) for switching or rectification in power electronics applications. Such a device is also called a power switch or, when used in an integrated circuit, a power IC. Power semiconductor devices are typically three-terminal devices—MOSFETs having a source, drain, and gate terminals; BJTs consist of three differently doped semiconductor regions and terminals: the emitter region, the base region, and the collector region. They can process power from a few watts for consumer electronics applications up to kilowatts in power converters for solar energy conversion or electric motor drives and even up to gigawatts in high voltage direct current transmission lines. In such applications, power dissipations from switching and conduction losses thermally limit the operation of the power semiconductors and contribute to energy loss.

For the past several decades or so, research and development of silicon power semiconductor devices are incrementally driven to improve the efficiency, power density, and reliability of power electronics through advances in devices, components, and converter integrations. However, silicon power devices are approaching the limits of the physics of existing device concepts. In the last ten years, many researchers have been focusing on building power devices in new materials such as wide bandgap (WBG) semiconductors, e.g., silicon carbide (SiC) and gallium nitride (GaN). WBG power devices have reduced losses compared with silicon power devices due to superior material properties. However, WBG devices are also using the same device physics and concepts as silicon power devices. For example, SiC IGBT is based on the same device structure and concept of Si IGBT.

Therefore, there is a strong benefit to improving the device concept of power semiconductor devices based on Si and WBG materials so that total energy loss in these devices is further reduced, regardless of the materials used.

### SUMMARY

Exemplary power semiconductor devices are disclosed that are configured with one or more conductivity-controlled device regions and structures that can actively modulate, via an additional conductivity-controlled (CC) terminal, the conductivity characteristics of the power device. Through this active modulation and device structure, the conductivity and, thus, the resistance of the power semiconductor device can be altered to substantially reduce losses (switching and conduction) of the device during operations. The exemplary conductivity-controlled power semiconductor devices (also referred to herein as “CCBT”) can provide substantial energy savings as well as reduce the thermal regulation requirements for any power application using additional conductivity-controlled circuitries. The conductivity-controlled device regions and structures can be applied to silicon-based power electronics, wide-bandgap power electronics, and any other classes of materials for power electronic devices. Simulation results described herein show a loss reduction of up to 80-90%, which is a substantial leap and improvement in the field of power semiconductor devices.

The loss improvements for the exemplary conductivity-controlled power semiconductor devices can be attributed to lower conduction loss. A power semiconductor device can switch to active mode operation when a voltage bias is applied across a junction diode structure located in the device. For silicon-based semiconductor devices, this offset voltage E₀ is typically between 0.7V and 1.0V. For silicon carbide-based devices, the offset voltage can be 3.2V. The exemplary conductivity-controlled device region and associated conductivity-controlled terminal can reduce this barrier by 80-90%.

The exemplary power semiconductor device can be employed as bipolar junction transistors (BJTs), metal-oxide-semiconductor field-effect transistors (MOSFETs), rectifiers, and diodes.

In an aspect, a power semiconductor device is disclosed comprising one or more conductivity-controlled devices comprising one or more conductivity-controlled diodes (e.g., 3 terminal diode), one or more conductivity-controlled transistors or thyristors (e.g., 3 terminal BJT, 4 terminal BJT, 4 terminal thyristor), or one or more conductivity-controlled FET-based devices (e.g., 4 terminal MOSFET). Each of the one or more conductivity-controlled devices can include a set of terminals including at least a first terminal, a second terminal, and a conductivity-controlled terminal; a first semiconductor region having a first doping polarity material that is coupled to the first terminal; a second semiconductor region having a second doping polarity material (i) in contact with the first semiconductor region and (ii) is coupled to the second terminal, the first and second semiconductor regions being configured to generate an electric field opposite in direction to electron flow, or hole, when a voltage is applied; and a third semiconductor region having a third doping polarity material that is opposite in doping polarity material to a doped region comprising either one of the first doping polarity material or the second doping polarity material, the third semiconductor region being coupled to the conductivity-controlled terminal to generate, when energized, a second electric field that reduces the resistance of the first and second semiconductor regions.

In some embodiments, one or more conductivity-controlled devices are configured as a diode with a conductivity-controlled terminal, a BJT with a conductivity-controlled terminal, a BJT with a conductivity-controlled terminal acting as the base terminal, a MOSFET with a conductivity-controlled terminal, or a thyristor with a conductivity-controlled terminal.

In some embodiments, the doped region comprising either one of the first doping polarity material or the second doping polarity material includes an N+ type doped material, and wherein the third semiconductor region has the third doping polarity material includes a P+ type doped material.

In some embodiments, the doped region comprising either one of the first doping

polarity material or the second doping polarity material includes a P+ type doped material, and wherein the third semiconductor region has the third doping polarity material includes an N+ type doped material.

In some embodiments (e.g., CC pnn diode (e.g., rectifier)), the second semiconductor region comprises an N− type substrate that has an N+ type doped cathode region, wherein the third semiconductor region comprises a P+ type doped conductivity-controlled region (e.g., comprising a P+ and P region) formed in the second semiconductor region, and wherein the first semiconductor region comprises an N+ type doped anode region formed over the oppositely doped P+ type doped conductivity-controlled region of the third semiconductor region.

In some embodiments (e.g., CC npp diode (e.g., rectifier)), the second semiconductor region comprises a P− type substrate that has a P+ type doped cathode region, wherein the third semiconductor region comprises an N+ type doped conductivity-controlled region formed in the second semiconductor region, and wherein the first semiconductor region comprises a P+ type doped anode region formed over the oppositely doped N+ type doped conductivity-controlled region of the third semiconductor region.

In some embodiments (e.g., CCBT), the second semiconductor region comprises an N− type substrate, wherein the third semiconductor region comprises (i) a first P+ type doped conductivity-controlled region formed in the second semiconductor region and (ii) a second P+ type doped conductivity-controlled region formed in the second semiconductor region, and wherein the first semiconductor region comprises (i) a first N+ type doped cathode-anode region that is formed in the oppositely doped first P+ type doped conductivity-controlled region and (ii) a second N+ type doped cathode-anode region that is formed in the oppositely doped second P+ type doped conductivity-controlled region.

In some embodiments (e.g., CCBT), the second semiconductor region comprises a P− type substrate, wherein the third semiconductor region comprises (i) a first N+ type doped conductivity-controlled region formed in the second semiconductor region and (ii) a second N+ type doped conductivity-controlled region formed in the second semiconductor region, and wherein the first semiconductor region comprises (i) a first P+ type doped cathode-anode region that is formed in the oppositely doped first N+ type doped conductivity-controlled region and (ii) a second P+ type doped cathode-anode region that is formed in the oppositely doped second N+ type doped conductivity-controlled region.

In some embodiments (e.g., CC pnn diode (e.g., rectifier)), the second semiconductor region comprises an N− type substrate that has an N+ type doped cathode region, wherein the first semiconductor region comprises an N+ type doped anode region formed in the second semiconductor region; and wherein the third semiconductor region comprises a P+ type doped conductivity-controlled region formed in the second semiconductor region that is oppositely doped and in proximity to the N+ type doped anode region of the first semiconductor region.

In some embodiments (e.g., CC npp diode (e.g., rectifier)), the second semiconductor region comprises a P− type substrate that has a P+ type doped cathode region, wherein the first semiconductor region comprises a P+ type doped anode region formed in the second semiconductor region; and wherein the third semiconductor region comprises an N+ type doped conductivity-controlled region formed in the second semiconductor region that is oppositely doped and in proximity to the P+ type doped anode region of the first semiconductor region.

In some embodiments (e.g., CC-BJT), the power semiconductor device comprises a conductivity-controlled bipolar-based device having a set of terminals comprising a base electrode as the first terminal, a collector electrode as the second terminal, an emitter electrode as a third terminal, and a conductivity-controlled electrode as the conductivity-controlled terminal.

In some embodiments (e.g., npn CC-BJT), the second semiconductor region comprises an N− type substrate that has an N+ type doped collector region, wherein the first semiconductor region comprises a P+ type doped base region formed in the P type semiconductor region that is layered over the second semiconductor region, the P type semiconductor region having formed an N+ type doped emitter region and the P+ type doped base region; and wherein the third semiconductor region comprises a P+ type doped conductivity-controlled region formed in the second semiconductor region that is oppositely doped and in proximity to the N+ type doped collector region of the second semiconductor region.

In some embodiments (e.g., pnp CC-BJT), the second semiconductor region comprises a P− type substrate that has a P+ type doped collector region, wherein the first semiconductor region comprises an N+ type doped base region formed in the N− type semiconductor region that is layered over the second semiconductor region, the N− type semiconductor region having formed a P+ type doped emitter region and the N+ type doped base region; and wherein the third semiconductor region comprises an N+ type doped conductivity-controlled region formed in the second semiconductor region that is oppositely doped and in proximity to the P+ type doped collector region of the second semiconductor region.

In some embodiments (e.g., CC-MOSFET), the power semiconductor device comprises a conductivity-controlled metal oxide semiconductor field emitting transistor-based device, the set of terminals comprising a source electrode as the first terminal, a drain electrode as the second terminal, a gate electrode as a third terminal, and conductivity-controlled electrode as the conductivity-controlled terminal.

In some embodiments (e.g., n-channel CC-MOSFET), the second semiconductor region comprises an N− type substrate that has an N+ type doped drain region, wherein the first semiconductor region comprises a P+ type doped base region formed in the P− type semiconductor region that is layered over the second semiconductor region, the P− type semiconductor region having formed an N+ type source region and the P+ type doped source region, wherein the gate electrode is formed on an oxide layer that is formed over a portion of the P− type semiconductor region and the N+ type emitter region of the P− type semiconductor region; and wherein the third semiconductor region comprises a P+ type doped conductivity-controlled region formed in the second semiconductor region that is oppositely doped and in proximity to the N+ type doped drain region of the second semiconductor region.

In some embodiments (e.g., p-channel CC-MOSFET), the second semiconductor region comprises a P− type substrate that has a P+ type doped drain region, wherein the first semiconductor region comprises an N+ type doped base region formed in the N− type semiconductor region that is layered over the second semiconductor region, the N− type semiconductor region having formed a P+ type source region and the N+ type doped source region, wherein the gate electrode is formed on an oxide layer formed over a portion of the N− type semiconductor region and the P+ type emitter region of the P− type semiconductor region; and wherein the third semiconductor region comprises an N+ type doped conductivity-controlled region formed in the second semiconductor region that is oppositely doped and in proximity to the P+ type doped collector region of the second semiconductor region.

In some embodiments, the power semiconductor device further includes a driver circuit that is coupled to the first terminal and the third terminal.

In some embodiments, the driver circuit provides a constant voltage between the first and third terminals or a constant current between the first and third terminals. The polarity of the voltage or current is to introduce conductivity modulation.

In some embodiments, the driver circuit comprises a MOSFET switch comprising a drain terminal, wherein the drain terminal is coupled to the first terminal, and the source terminal is coupled to the rest of the driver circuit.

In some embodiments, the driver circuit comprises a MOSFET switch comprising a gate, drain, and source terminals, wherein the source terminal is coupled to the third terminal, and the drain terminal is coupled to the rest of the driver circuit.

In some embodiments, the driver circuit timing is synchronized with the fourth terminal.

In some embodiments, the driver circuit timing is not synchronized with the fourth terminal.

In some embodiments, the power semiconductor device is configured for high voltage (>600V) operation.

In some embodiments, the semiconductor material is silicon, silicon carbide (SiC), gallium nitride, or other materials.

### BRIEF DESCRIPTION OF THE DRAWINGS

The accompanying drawings, which are incorporated in and constitute a part of this specification, illustrate embodiments and, together with the description, serve to explain the principles of the methods and systems.

FIGS. 1A, 1B, 1C, and 1D show examples of power semiconductor CC-MOSFET devices configured with one or more conductivity-controlled device regions and structures that can actively modulate, via a conductivity-controlled terminal, the conductivity characteristics of the power device in accordance with an illustrative embodiment.

FIGS. 2A and 2B show examples of power semiconductor CC-BJT devices configured with one or more conductivity-controlled device regions and structures that can actively modulate, via a conductivity-controlled terminal, the conductivity characteristics of the power device in accordance with an illustrative embodiment.

FIGS. 3A and 3B show examples of power semiconductor CC-rectifier devices configured with one or more conductivity-controlled device regions and structures that can actively modulate, via a conductivity-controlled terminal, the conductivity characteristics of the power device in accordance with an illustrative embodiment.

FIG. 4 shows examples of power semiconductor bidirectional CCBT devices configured with one or more conductivity-controlled device regions and structures that can actively modulate, via a conductivity-controlled terminal, the conductivity characteristics of the power device in accordance with an illustrative embodiment.

FIG. 5 shows structures of conventional BJTs, MOSFETs, and IGBTs device structures to illustrate the difference between the invention embodiments and existing devices.

FIGS. 6A, 6B, and 6C each shows plots of voltage-current (VI) curves illustrating the energy loss for various power semiconductor devices as a comparison to certain conductivity-controlled power semiconductor devices described herein.

FIG. 7 shows a comparison of device conductivity, Rₒₙ₋ₛₚ, for various power semiconductor devices to certain conductivity-controlled power semiconductor devices described herein.

FIGS. 8A, 8B, and 8C show example implementations of the conductivity-controlled metal oxide semiconductor field-effect transistor (CC-MOSFET) devices of FIGS. 1A and 1B configured with a conductivity-controlled device region and structure in accordance with an illustrative embodiment.

FIGS. 9A, 9B, 9C, and 9D show example methods of operating a conductivity-controlled bipolar transistor device in accordance with an illustrative embodiment.

FIGS. 9E, 9F, and 9G show example implementations of a CCBT drive circuit for a conductivity-controlled bipolar transistor device in accordance with an illustrative embodiment.

FIGS. 10A, 10B, and 10C show example implementations of a conductivity-controlled bipolar junction transistor (CC-BJT) device in accordance with an illustrative embodiment.

FIGS. 11A, 11B, 11C, 11D, 11E, and 11F show plots of simulation results of a conductivity-controlled resistor (CC-resistor) device in accordance with an illustrative embodiment.

FIGS. 12A, 12B, 12C, and 12D show plots of simulation results of a conductivity-controlled metal bipolar junction transistor (CC-MOSFET) device in accordance with an illustrative embodiment.

FIG. 13A shows an image of the measured voltage-current (VI) curves of a 1500V CC-rectifier device.

FIG. 13B shows an image of the measured voltage-current (VI) curves of a 15000V SiC CC-BJT (three terminal) device.

### DETAILED DESCRIPTION

Some references, which may include various patents, patent applications, and publications, are cited in a reference list and discussed in the disclosure provided herein. The citation and/or discussion of such references is provided merely to clarify the description of the disclosed technology and is not an admission that any such reference is “prior art” to any aspects of the disclosed technology described herein. In terms of notation, “[n]” corresponds to the nth reference in a first list. All references cited and discussed in this specification are incorporated herein by reference in their entirety and to the same extent as if each reference was individually incorporated by reference.

### Example Device Type #1-Conductivity-Controlled Metal-Oxide-Semiconductor-Field-Effect Transistor (CC-MOSFET) Device

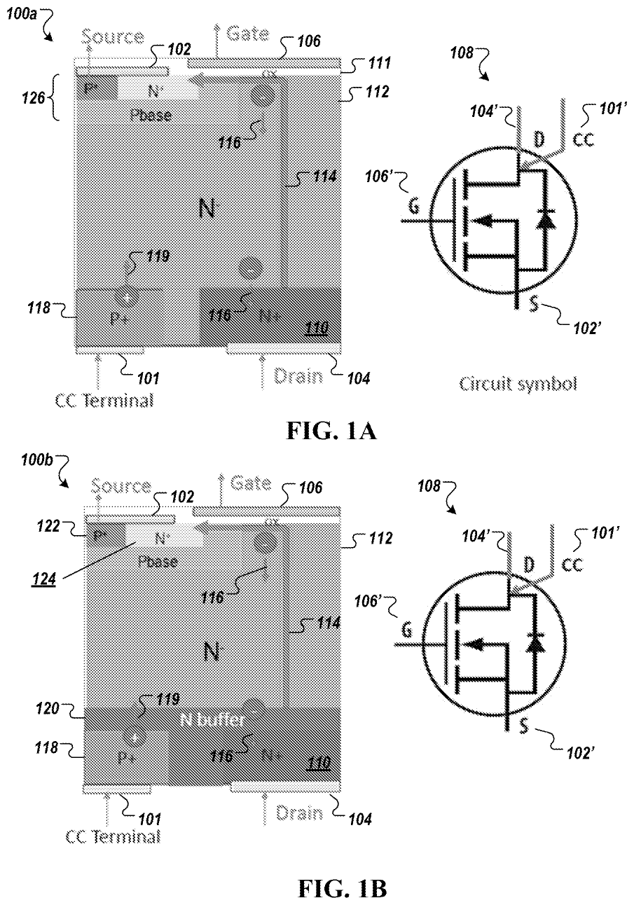

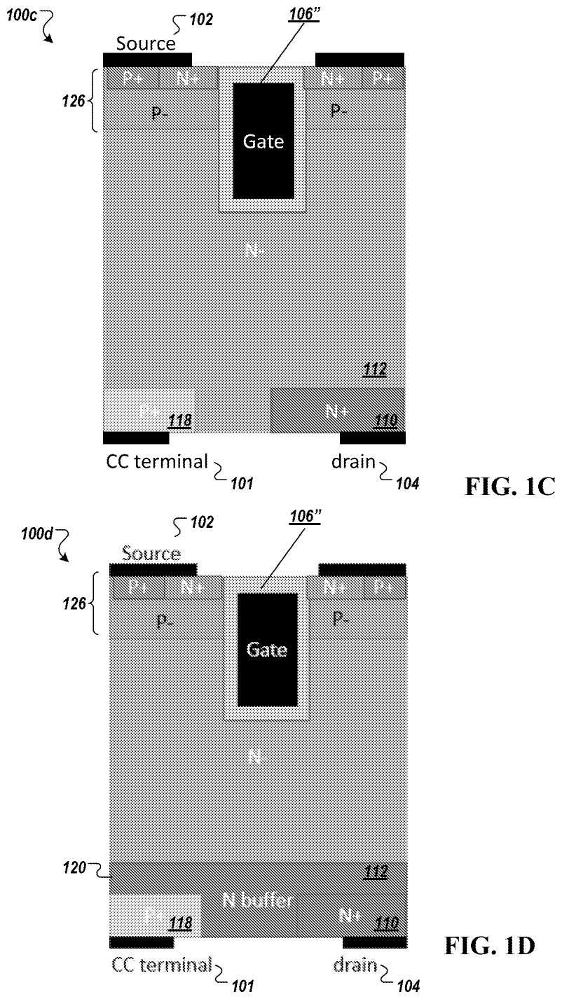

FIGS. 1A, 1B, 1C, and 1D show examples of power semiconductor CC-MOSFET devices 100 (shown as 100a, 100b, 100c, 100d) configured with one or more conductivity-controlled device regions and structures that can actively modulate the conductivity characteristics of the power device in accordance with an illustrative embodiment.

In the example shown in FIGS. 1A, 1B, 1C, and 1D, the CC-MOSFET devices 100a, 100b, 100c, and 100d each include a MOSFET structure having a set of terminals including at least a first terminal 102 (shown as “Source” 102), a second terminal 104 (shown as “Drain” 104), a third terminal 106 (shown as “Gate” 106), and an additional conductivity-controlled terminal 101 (shown as “CC Terminal” 101). The second terminal 104 (e.g., drain) of the CC-MOSFET device is connected to a first semiconductor region 110 having a first doping polarity material, and the third terminal 106 (e.g., gate) is connected to the second semiconductor region 112 (shown through an oxide layer 111) having a second doping polarity material (N− doped material) in contact with the first semiconductor region 110. The first and second semiconductor regions 110, 112 can generate an electric field along the path 114 opposite in direction 116 of the electron flow (depending on device 100 being configured as an N− type device or a P− type device) when energized to allow current to flow through the device. In the example shown in FIG. 1, an N− type CC-MOSFET includes the first semiconductor region 110 fabricated as a drain region with an N⁺ doped material, and the second semiconductor region 112 is fabricated as a bulk semiconductor material with an N⁻ type material. The symbol 108 of the CC-MOSFET devices 100a, 100b, 100c, 100d is shown as having the first, second, and third terminals (shown as source terminal “S” 102′, drain terminal “D” 104′, and gate terminal “G” 106′), and the conductivity-controlled terminal (shown as “CC” 101′).

The CC-MOSFET devices 100a, 100b, 100c, 100d form the conductivity-controlled region and structure between the first semiconductor region 110 and the second semiconductor region 112 that can modulate the resistance for the device 100 (e.g., the “on” resistance) when energized by the third semiconductor region 118 via the conductivity-controlled terminal 101 and the gate terminal 106 is positively biased with respect to the source terminal. Electron current flows from drain to source via path 114. Without region 118 and terminal 101, the resistance to electron current flow is determined by the background doping of the N− region 112. With region 118 and terminal 101, when energized, it effectively reduces the respective resistance of the conductivity-controlled region to electron and hole flows (shown by arrow 114) by at least 1000 times in magnitude, thereby reducing the conduction losses for the device 100a, 100b, 100c, and 100d. The third semiconductor region 118 can be fabricated with a third doping polarity material (e.g., a P⁺ material in FIGS. 1A, 1B, 1C, and 1D) that is opposite in doping polarity material to the first doping polarity material 110 or the second doping polarity material 112. The third semiconductor region 118 can be coupled to the conductivity-controlled terminal 101 to generate, when energized, a second electric field and hole current flow 119 that reduces the resistance to electron flow 114 in the first and second semiconductor regions 110, 112. Put another way, the conductivity-controlled terminal 101 injects a small amount of holes which will result in a larger electron current flow 114 over that of the conventional flow between the first and second semiconductor material. The N− device for a CC-MOSFET device may include a P+/N+ and Pbase structure 126 for the source terminal region.

FIG. 1A shows a configuration of the power semiconductor CC-MOSFET device 100. FIG. 1B shows the same device 100 of FIG. 1A, which can include additional structures, e.g., a buffer layer 120 (shown in the example of an N− type device as an “N buffer” 120). The function of the buffer layer is to prevent premature breakdown of the device when the switch is not conducting current. FIG. 1C shows a CC-MOSFET configured with a trench gate (shown as 106″) on the top structure. FIG. 1D shows a CC-MOSFET configured with a trench gate (shown as 106″) on the top structure together with an additional N buffer layer.

A corresponding P− device (not shown) can be similarly fabricated with the conductivity control terminal 101 and the third semiconductor region 118. The P device for a CC-MOSFET device may include a P⁻ bulk second semiconductor region (112), an N+ first semiconductor region (110), an N+ third semiconductor region (118), and an N+/P+ and Nbase structure for the source terminal region.

Conductivity control, as provided in the conductivity-controlled semiconductor device, is configured with a conductivity control region (e.g., regions 110, 112) that is opposite in doping to another doped region (e.g., region 118) that is used in the semiconductor device to affect a current flow of the same direction. A power semiconductor device, when conducting, is in effect, a resistor (e.g., through region 110, 112) to which current can flow from a positive terminal 104 to a negative terminal 102. The electric field direction is from region 110 toward the channel region. In the power semiconductor device, a voltage is applied by the conductivity control region 118, which will generate an additional electric field in the same direction as the electric field from 110 to the channel region. This paralleled electric field direction and the injection of the hole (e.g., 119) will significantly enhance the electron current flow (e.g., 116). The conductivity control region (e.g., 118), as an active device component, can alter the resistance or conductivity of the bulk region (e.g., 112) of the semiconductor device to the amount of electrons and holes that can flow through it hence substantially reducing the electric field that is required to cause a similar current flow to occur. This structure thereby reduces the resistance of this resistor of the device, which can lead to substantially lower power losses and heat dissipation.

In each of the conductivity-controlled bipolar transistor (CCBT) devices of FIGS. 1-4 (e.g., CC-MOSFET, CC-BJT, CC-R), the CCBT devices include a set of terminals including at least a first terminal (104, 204, 304), a second terminal (106, 206, 306), and sometimes a third terminal, and an additional conductivity-controlled terminal. The first and second terminals are connected, respectively, to (i) a first semiconductor region (110, 210, 310) having a first doping polarity material and (ii) a second semiconductor region (112, 212, 312) having a second doping polarity material in contact with the first semiconductor region (e.g., 110, 210, 310, respectively). The first and second semiconductor regions (110 and 112, 210 and 212, and 310 and 312) can generate an electric field opposite in direction to electron flow or in the same direction of the hole (depending on it being configured as an N− type device or a P− type device) when energized to allow current to flow through the device.

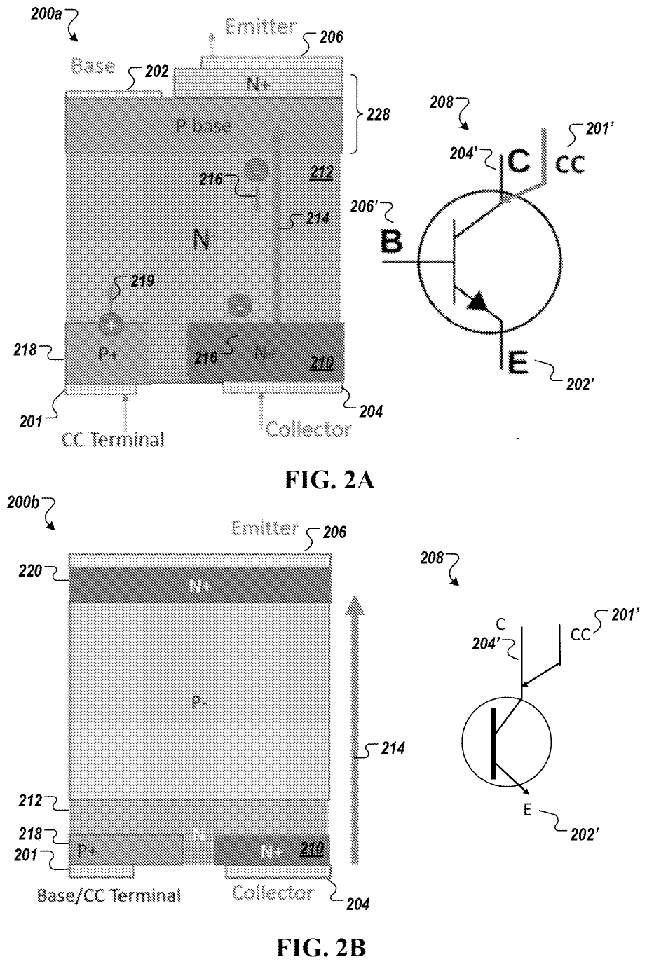

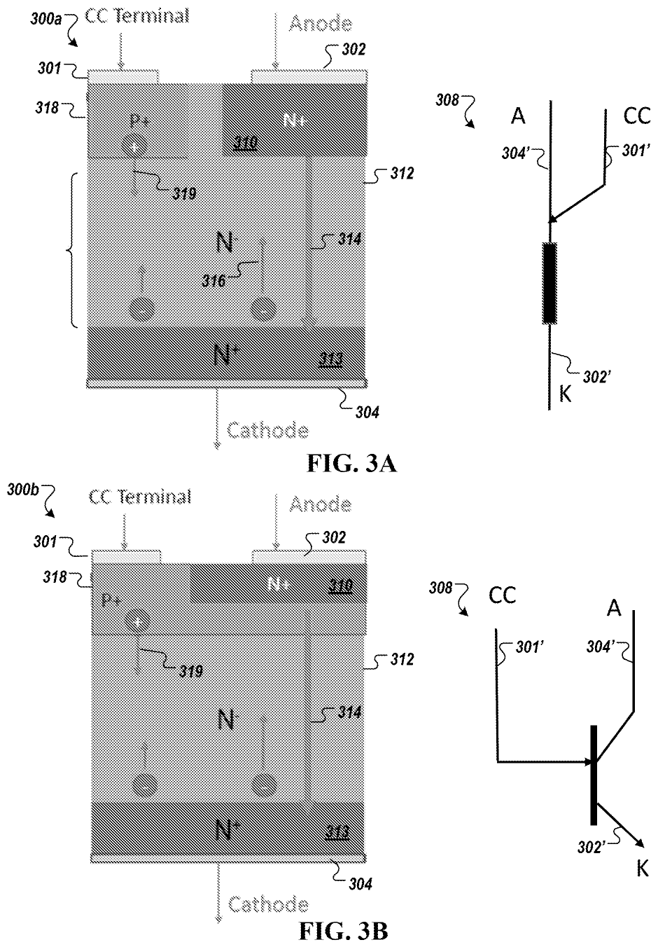

In the examples of a CC-MOSFET 100 (FIGS. 1A, 1B, 1C, 1D), the first semiconductor region (110) is the drain comprising an N⁻ doped region, and the second semiconductor region (112) is the bulk semiconductor material comprising an N⁻ type material. In the example of CC-BJT (FIGS. 2A and 2B), the first semiconductor region (210) is the collector comprising the N⁺ doped region, and the second semiconductor region (212) is the bulk semiconductor material comprising an N⁻ type material. In the example of the CC-rectifier (FIGS. 3A and 3B), the first semiconductor region (310) is the anode comprising the N⁺ doped region, and the second semiconductor region (312) is the bulk semiconductor material comprising N material. The first semiconductor region (110, 210, 310) and the second semiconductor region (112, 212, 312) effectively have an “on” resistance when the device is actuated to conduct current. The exemplary CCBT devices further include the conductivity-controlled region and structure (118, 218, 318) that can modulate, when energized by its respective CC terminal (when the device is also energized), the controllable resistance for the device (e.g., the “on” resistance) to effectively reduce that respective resistance to electron and hole flow (shown by the arrow in each of the CC devices), by 1000×, thereby reducing the conduction losses for the device.

In each of the example CCBT devices, the CCBT device includes a third semiconductor region (118, 218, 318) having a third doping polarity material that is opposite in doping polarity material to a doped region comprising either one of the first doping polarity material (110) or the second doping polarity material (212, 312). The third semiconductor region (118, 218, 318) is coupled to the conductivity-controlled terminal (101, 201, 301) to generate, when energized, a second electric field and hole current injection that reduces the resistance to electron and hole flow of the first and second semiconductor regions (110 and 112, 210 and 212, and 310 and 312). Put another way, the conductivity-controlled terminal serves as a conduit for electron and hole flow that becomes the primary conduct of flow over that of the conventional flow between the first and second semiconductor material.

As shown in the devices, the CCBT devices can be fabricated on both sides (opposite surfaces) of a semiconductor device. The CCBT devices can also be readily fabricated on a single surface.

### Example Device Type #2-Conductivity-Controlled Bipolar-Junction Transistor (CC-BJT) Device

FIGS. 2A and 2B show examples of power semiconductor CC-BJT devices 200 (shown as 200a and 200b) configured with one or more conductivity-controlled device regions and structures that can actively modulate the conductivity characteristics of the power device in accordance with an illustrative embodiment.

In the example shown in FIG. 2, the CC-BJT devices 200a, 200b each include a BJT structure having a set of terminals including at least a first terminal 202 (shown as “Emitter” 202), a second terminal 204 (shown as “Collector” 204), a third terminal 206 (shown as “Base” 206), and an additional conductivity-controlled terminal 201 (shown as “CC Terminal” 201). The second terminal 204 (e.g., collector) of the CC-BJT device is connected to a first semiconductor region 210 having a first doping polarity material (N+ doped material), and the first terminal 202 (e.g., collector) is connected to the second semiconductor region 212 having a second doping polarity material in contact with the first semiconductor region 110. The first and second semiconductor regions 210, 212 can generate an electric field at the path 214 opposite in direction 216 to electron flow or the same direction of hole flow (depending on device 200 being configured as an N− type device or a P− type device) when energized to allow current to flow through the device. In the example shown in FIG. 2, an N− type CC-BJT includes the first semiconductor region 210 fabricated as a collector region with an N⁺ doped material, and the second semiconductor region 212 is fabricated as a bulk semiconductor material with an N⁻ type material. The symbol 208 of the CC-BJT devices 200a, 200b is shown having the first, second, and third terminals (shown as emitter terminal “E” 202′, collector terminal “C” 204′, and base terminal “B” 206′), and the conductivity-controlled terminal (shown as “CC” 101′).

The CC-BJT devices 200a, 200b form the conductivity-controlled region and structure between the first semiconductor region 210 and the second semiconductor region 212 that can modulate the controllable resistance for the device 200 (e.g., the “on” resistance) when energized by the third semiconductor region 218 via the conductivity-controlled terminal 201 and the base terminal 202 is positively biased with respect to the emitter terminal 208. Electron current flows from collector to emitter via path 214. Without region 218 and terminal 201, the resistance to electron current flow is determined by the background doping of the N− region 212. With region 218 and terminal 201, when energized, it effectively reduces the respective resistance of the conductivity-controlled region to electron and hole flow (shown by arrow 214), thereby reducing the conduction losses for the device 200a, 200b. The third semiconductor region 218 can be fabricated with a third doping polarity material (e.g., a P⁺ material in FIGS. 2A and 2B) that is opposite in doping polarity material to the first doping polarity material 210. The third semiconductor region 218 can be coupled to the conductivity-controlled terminal 201 to generate, when energized, a second electric field and hole current flow 219 that reduces the resistance to electron flow 214 in the first and second semiconductor regions 210, 212. The N− device for a CC-BJT device may include an N+ and Pbase structure 228 for the emitter terminal region.

FIG. 2A shows a configuration of the power semiconductor CC-BJT device 200 with four terminals. The device is switched on and off via the base terminal and the CC terminal. FIG. 2B shows a CC-BJT with only three terminals. In this case, the CC terminal is also acting as the base terminal. The function of the buffer layer is to prevent premature breakdown of the device when the switch is not conducting current. The device is switched on and off via the CC/CC terminal 201. A corresponding P− device (not shown) can be similarly fabricated with the conductivity control terminal 201 and the third semiconductor region 218. The P device for a CC-BJT device may include a P− bulk second semiconductor region (212), a P+ first semiconductor region (210), an N+ third semiconductor region (118), and a P+ and Pbase structure for the emitter terminal region.

### Example Device Type #3-Conductivity-Controlled Rectifier (CCR) Device

FIGS. 3A and 3B show examples of power semiconductor CC-rectifier devices 300 (shown as 300a and 300b) configured with one or more conductivity-controlled device regions and structures that can actively modulate the conductivity characteristics of the power device in accordance with an illustrative embodiment.

In the example shown in FIG. 3, the CC-BJT devices 300a, 300b each include a rectifier structure having a set of terminals including at least a first terminal 302 (shown as “anode” 302), a second terminal 304 (shown as “cathode” 304), and an additional conductivity-controlled terminal 301 (shown as “CC Terminal” 301). The first terminal 302 (e.g., anode) of the CC-rectifier device is connected to a first semiconductor region 310 having a first doping polarity material (N+ doped material), and the second terminal 304 (e.g., cathode) is connected to the second semiconductor region 313 (N+ doped material) having a second doping polarity material in contact with a bulk semiconductor material (N− doped material) in contact 312 with the first semiconductor region 310. The first, second, and bulk semiconductor regions 310, 313, 312 can generate an electric field along the path 314 opposite in direction 316 to electron flow or the same direction as hole flow (depending on device 300 being configured as an N− type device or a P− type device) when energized to allow current to flow through the device. In the example shown in FIG. 3, an N− type CC-rectifier includes the first semiconductor region 310 fabricated as an anode region with an N⁺ doped material, and the second semiconductor region 313 is fabricated as a second N+ doped material in a bulk semiconductor material 312 with an N⁻ type material. The symbol 308 of the CC-rectifier devices 300a, 300b is shown having the first and second terminals (shown as cathode terminal “K” 302′ and anode terminal “A” 304′), and the conductivity-controlled terminal (shown as “CC” 301′).

The CC-rectifier devices 300a, 300b form the conductivity-controlled region and structure between the first semiconductor region 310 and the second semiconductor region 313 through the semiconductor bulk region 312 that can modulate the controllable resistance for the device 300 (e.g., the “on” resistance) when energized by the third semiconductor region 318 via the conductivity-controlled terminal 301 and the anode terminal 302 is positively biased with respect to the cathode terminal 304. Electron current flows from the anode to cathode via path 314. Without region 318 and terminal 301, the resistance to electron current flow is determined by the background doping of the N− region 312. With region 318 and terminal 301, when energized, it effectively reduces the respective resistance of the conductivity-controlled region to electron and hole flow (shown by arrow 314), thereby reducing the conduction losses for the device 300a, 300b. The third semiconductor region 318 can be fabricated with a third doping polarity material (e.g., a P⁺ material in FIGS. 3A and 3B) that is opposite in doping polarity material to the first doping polarity material 310. The third semiconductor region 318 can be coupled to the conductivity-controlled terminal 301 to generate, when energized, a second electric field and hole flow 319 that reduces the resistance to electron and hole flow of the first, second, and bulk semiconductor regions 310, 313, 312.

FIG. 3A shows a configuration of the power semiconductor CC-rectifier device 300. FIG. 3B shows the same device 300 of FIG. 3A, which can include the third semiconductor region 318 extending around the first semiconductor region 310. A corresponding P− device (not shown) can be similarly fabricated with the conductivity control terminal 301 and the third semiconductor region 318. The P device for a CC-rectifier device may include a P− bulk second semiconductor region (312), a P+ first semiconductor region (310) for the anode terminal region, an N+ third semiconductor region (318), and a P+ structure (313) for the cathode terminal region.

FIG. 3A shows a configuration of the power semiconductor CC-rectifier device 300. FIG. 3B shows the same device 300 of FIG. 3A, which can include the third semiconductor region 318 extending around the first semiconductor region 310. A corresponding P− device (not shown) can be similarly fabricated with the conductivity control terminal 301 and the third semiconductor region 318.

The CC-rectifier device (e.g., 300a, 300b) is a three-terminal power semiconductor device that can be made of Si, SiC, GaN, or other materials.

Though the device may include three terminals, it functions as a diode. Current flows from the anode to cathode when the CC terminal is energized. The device will block voltage in the cathode-anode direction when the anode terminal is disconnected, using one or more of the drive circuits described. The high voltage is supported by the reverse biased junction formed by region 318 and 312.

In FIG. 3A, an N− type conductivity-controlled rectifier device can be fabricated by adding an N+ doped layer to the top surface of a diode (e.g., traditional diode) to form a new “anode terminal” (shown as “Anode”). The conventional anode P+ dope layer then serves as the conductivity-controlled region and is coupled to an additional conductivity-controlled terminal (shown as “CC Terminal”). Reverse blocking can be achieved by floating the Anode terminal using a drive circuit (e.g., 950) described herein.

A P− type conductivity-controlled rectifier device can be fabricated on a P− substrate having a cathode region formed of a P+ doped material. The anode region can be a P+ doped region, and the conductivity-controlled region can be formed of an N+ doped material that is opposite of the anode region.

In the example of the CC-rectifier device of FIG. 3A, to turn on the CC-rectifier diode, a constant current bias or voltage can be applied to the CC terminal while a positive voltage is applied between the anode and cathode terminals. To turn off the CC-rectifier, the constant current bias, Icc, or voltage, Vcc, can be removed while a zero or negative voltage is applied to the anode and cathode terminals.

FIG. 3B shows another N− type conductivity-controlled rectifier device configured with a conductivity-controlled region. The conductivity-controlled rectifier device of FIG. 3B can ensure the reverse breakdown performance by forming a conductivity-controlled region comprising a P+ doped layer over the N− substrate. The anode layer comprising the N+ doped region can be formed within the P− type CC layer. The structure is actually the same as a traditional BJT but operates as a CCR. This means that all conventional BJT can be used as a CCR.

### Example Device Type #4-Bidirectional Conductivity-Controlled Bipolar Transistor (bi-directional CCBT) Device

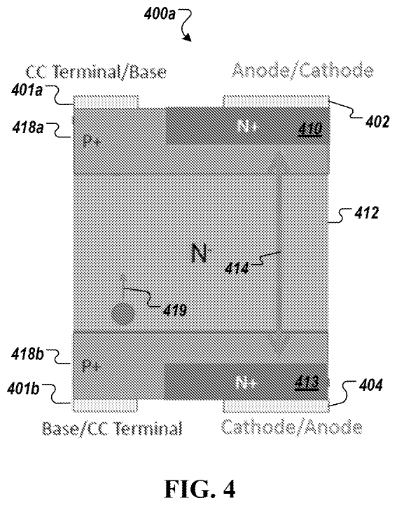

FIG. 4 shows examples of power semiconductor bidirectional CCBT devices 400 configured with one or more conductivity-controlled device regions and structures that can actively modulate the conductivity characteristics of the power device in accordance with an illustrative embodiment.

In the example shown in FIG. 4, the bidirectional CCBT device 3400 includes a rectifier structure having a set of terminals, including at least a first terminal 402 (shown as “anode/cathode” 402), a second terminal 404 (shown as “cathode/anode” 404), and two additional conductivity-controlled terminals show as a first conductivity-controlled terminal 401a (shown as “CC Terminal/base” 401a) and a second conductivity-controlled terminal 401b (shown as “base/CC Terminal” 401b). The first terminal 402 (e.g., anode/cathode) of the bidirectional CCBT device is connected to a first semiconductor region 410, having a first doping polarity material (N+ doped material), and the second terminal 404 (e.g., cathode) is connected to the second semiconductor region 313 (N+ doped material) having a second doping polarity material in contact with a bulk semiconductor material (N− doped material). The first semiconductor region 410 and the second semiconductor region 413 are each in contact 312 with the bulk semiconductor region 412. The first, second, and bulk semiconductor regions 410, 413, 412 can generate an electric field along path 414 opposite in direction to electron flow or the same direction to hole flow (depending on device 400 being configured as an N− type device or a P− type device) when energized to allow current to flow through the device. In the example shown in FIG. 4, a bidirectional N− type CCBT device includes the first semiconductor region 410 fabricated as an anode region (when biased in a first polarity and as a cathode with an opposite bias) with an N⁻ doped material, and the second semiconductor region 413 is fabricated as a cathode region (when biased in the first polarity and as an anode with the opposite bias) with a second N+ doped material.

The bidirectional CCBT device 400 forms the conductivity-controlled region and structure between the first semiconductor region 410 and the second semiconductor region 413 through the semiconductor bulk region 412 that can modulate the controllable resistance for the device 400 (e.g., the “on” resistance) when energized by the third semiconductor region 418a or 418b, depending on the bias, via the conductivity-controlled terminal 401a or 401b, respectively, and an anode terminal (e.g., 402 or 404) is positively biased with respect to a cathode terminal. Without region 418a, 418b and terminal 401a, 401b, the resistance to electron current flow is determined by the background doping of the N− region 412. With region 418a, 418b and terminal 401a, 402a, when energized, it effectively reduces the respective resistance of the conductivity-controlled region to electron and hole flow (shown by arrow 414 for one bias direction), thereby reducing the conduction losses for the device 400. The third semiconductor region 418a or 418b can be fabricated with a third doping polarity material (e.g., a P⁺ material in FIG. 4) that is opposite in doping polarity material to the first doping polarity material 310 and the second doping polarity material 313. The third semiconductor region 418a or 418b can be coupled to the conductivity-controlled terminal 401a and 401b, respectively, to generate, when energized, a second electric field and hole flow 419 that can reduce the resistance to electron flow of the first, second bulk semiconductor regions 410, 413, 412.

In the example of FIG. 4, the bidirectional CCBT device 400 is a four-terminal power semiconductor device that can be made of Si, SiC, GaN, or other materials. The bidirectional CCBT device 400 can be fabricated by having the same structure on both sides of the chip. It can also be made on the same side of the chip. Depending on the current direction, the role of the CC terminal is either as a Base or a CC terminal.

### Improved Loss Operation Using the Exemplary Conductivity-Controlled Power Semiconductor Devices

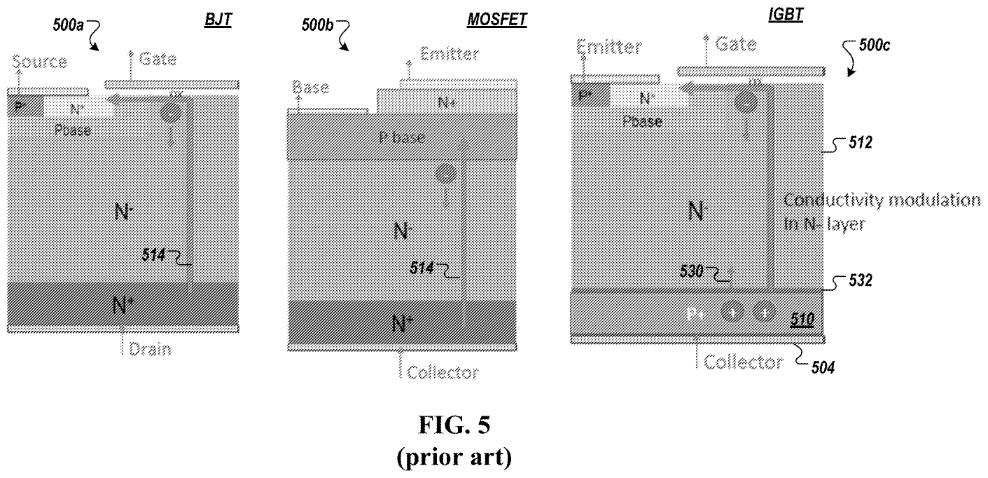

Further description of the operation and physics of the conductivity-controlled power semiconductor devices of FIGS. 1A, 1B, 2A, 2B, 3A, 3B, and 4 are now provided. As an initial matter, FIG. 5 shows structures for examples of conventional BJTs (500a), MOSFETs (500b), and IGBTs (500c) that can be fabricated as Si, SiC, GaN devices to illustrate the difference between the invention embodiments and existing devices. They can be modified as described herein with the conductivity-controlled regions and terminals to provide the conductivity-controlled power semiconductor devices.

In FIG. 5, both the conventional MOSFET and BJT N− type devices (500a and 500b) are shown to conduct current 514 through a single carrier electron (unipolar) drift. For P− type devices (not shown), the current can only flow by hole mobility. The “on” resistance can be statically determined by a breakdown voltage in which the normalized resistance can be calculated per Equation 1. The resistance can increase rapidly hence generating more losses when the power devices are designed for high breakdown voltages.

$${R}_{on ‐ sp} = \frac{4 {BV}^{2}}{μ ε {E}_{c}^{3}} \qquad ( Eq . 1 )$$

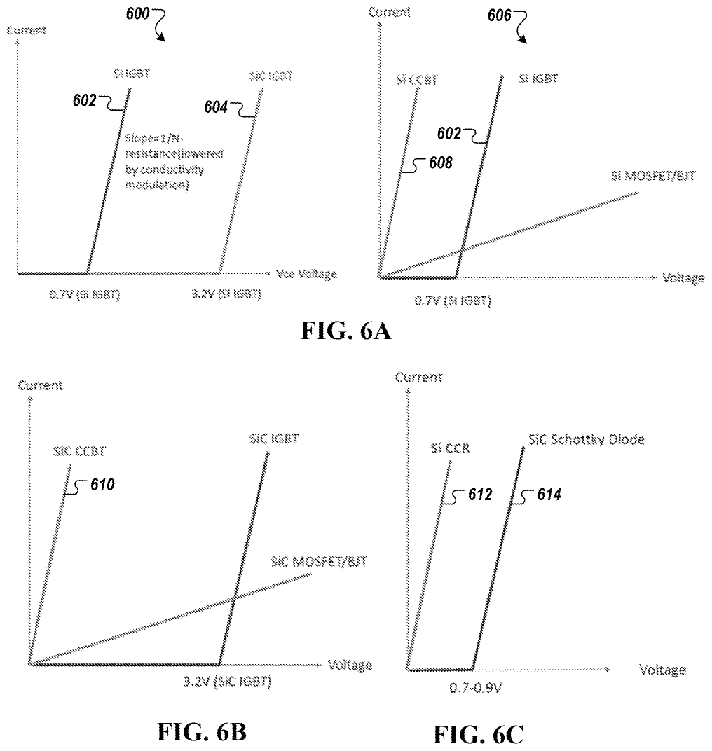

For a Si device with 100 μm/1e¹⁴ doping drift region (e.g., typical of a 1200V device), the normalized resistance would be Rₒₙ₋ₛₚ=462 mohm-cm². The two devices 500a, 500b can be considered to have no conductivity modulation/or bipolar current conduction in the drift layer. In the example of an IGBT device (500c), the minority carrier (hole) injection 530 is provided by the p⁺ anode layer 510 (shown connected to a collector terminal 504), which can cause conductivity modulation. The device is defined at the fabrication stage, however, has fixed, single conductivity modulation characteristics in the N region 512. The P⁺/N junction 532 of the device 500c still requires a bias voltage, e.g., 0.7 V, for conduction to occur, resulting in a total IGBT forward drop of greater than 1 V. FIGS. 6A and 6B are diagrams each showing example operating properties for a CCBT device (e.g., 100a, 100b, 100c, 100d, 200a, 200b, 300a, 300b, 400) and their conventional counterparts. In FIG. 6A, diagram 600, the VI curve illustrates the energy loss (i.e., forward drop) for a Si IGBT (602) and a SiC IGBT (604). The energy loss for SiC IGBT requiring 3.2 V to turn on is much higher.

FIG. 6, diagram 606 shows a second VI curve illustrating the energy loss 608 for an exemplary conductivity-controlled power semiconductor device (e.g., 100a, 100b, 100c, 100d, 200a, 200b, 300a, 300b, 400). Notably, FIG. 6A, diagram 606, in contrast to FIG. 6A, diagram 600, shows the VI characteristics 608 of an exemplary conductivity-controlled power semiconductor devices turning “on” at a voltage bias that is close to “0” V. This reduction in forward biasing operation effectively reduces the energy to operate the device (e.g., 100a, 100b, 100c, 100d, 200a, 200b, 300a, 300b, 400) by 1V per 1 A (i.e., 1 W per 1 A) for a comparably-sized device of a similar design (e.g., 500a, 500b, 500c) to those shown in FIG. 5. If it is assumed that over 70 billion Amperes of IGBT capacity are manufactured in a year, and further assume a reduction of switching and conduction losses by 1 W/1 A per device, through the implementation of the exemplary design to every manufactured IGBT device, that power saving would be about 70 billion watts of electricity. This is equivalent to seventy (70) 1000 MW nuclear power plants.

The exemplary conductivity-controlled power semiconductor devices described herein are a breakthrough in power semiconductor technology that can be implemented wholly through device design. The exemplary conductivity-controlled power semiconductor devices can be applied broadly across any applicable semiconductor material used for power semiconductor device applications. The exemplary conductivity-controlled regions and structures can be integrated into power semiconductor devices to extend the bipolar conduction mechanism to a device fabricated from SiC, GaN, and other wide bandgaps (WBG) materials. FIG. 6B is a diagram showing an example VI curve for the exemplary conductivity-controlled power semiconductor devices fabricated using SiC (shown as “SiC CCBT”) 610. Indeed, the SiC-based CCBT (see line 610) also would have a similar forward drop characteristic to the Si-based CCBT device (see line 608).

In addition, the exemplary conductivity-controlled regions and structures can be employed to extend to breakdown voltage capability of power semiconductor devices substantially, e.g., up to 50kV, while only requiring less than a 1V forward drop (not shown).

In addition, the exemplary conductivity-controlled regions and structures can be integrated into diodes to provide a conductivity-controlled rectifier (hereinafter referred to as “CCR” or “CC-rectifier”). FIG. 6C is a diagram showing the VI curve characteristics for a CC-rectifier (shown as “Si CCR”) (612) as compared to a SiC Schottky diode (614). It can be observed that the exemplary conductivity-controlled rectifier has comparable, if not superior, performance to the state-of-the-art SiC Schottky diode. Notably, the silicon-based CC-rectifier (see line 612) would have lower silicon technology associated cost while providing SiC-like performance (see line 614) and can be fabricated to operate in an extremely high voltage range, 600V to 10 kV, using silicon-based material.

Simulation results described herein show that the silicon-based CCBT device can exceed loss performance over SiC BJT, SiC MOSFET, etc. The improvements of the CCBT device can be 100× over Si BJT, Si MOSFET. By applying the CCBT device design to SiC devices, it is expected that the device would improve in loss performance by over 100×.

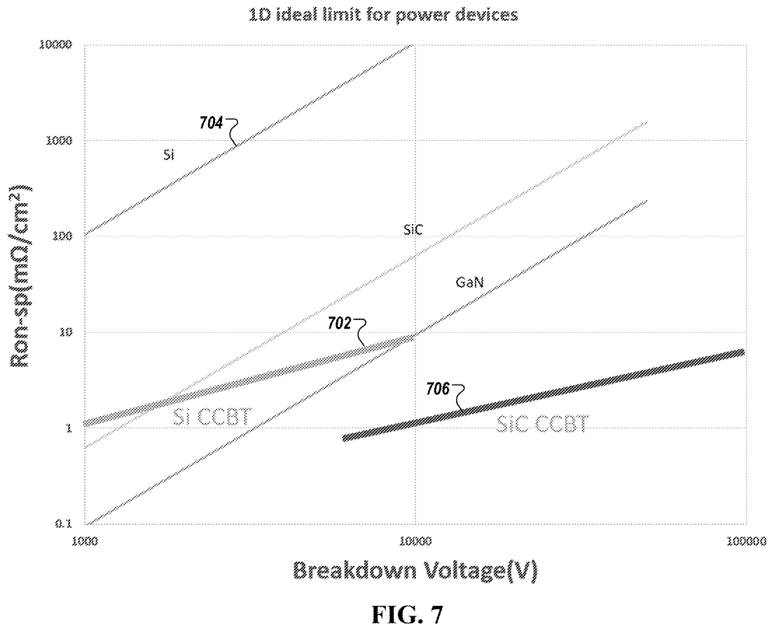

FIG. 7 shows a comparison of device conductivity, Ron-sp. for various Si and SiC devices. The performance of a Si-based CCBT device (shown as “Si CCBT”) is shown as 702. The Si-based CCBT is shown to have substantially lower Rₒₙ₋ₛₚ characteristics compared to a corresponding si-based device (704). Similarly, the Si-based CCBT is shown to have substantially lower Rₒₙ₋ₛₚ characteristics compared to SiC devices for higher breakdown voltage devices (the example shows the cross point at 2000 V). The Rₒₙ₋ₛₚ characteristics of a SiC CCBT device (706) are substantially lower than that of its SiC counterpart.

### Example: 1—Fabricated CC-MOSFET

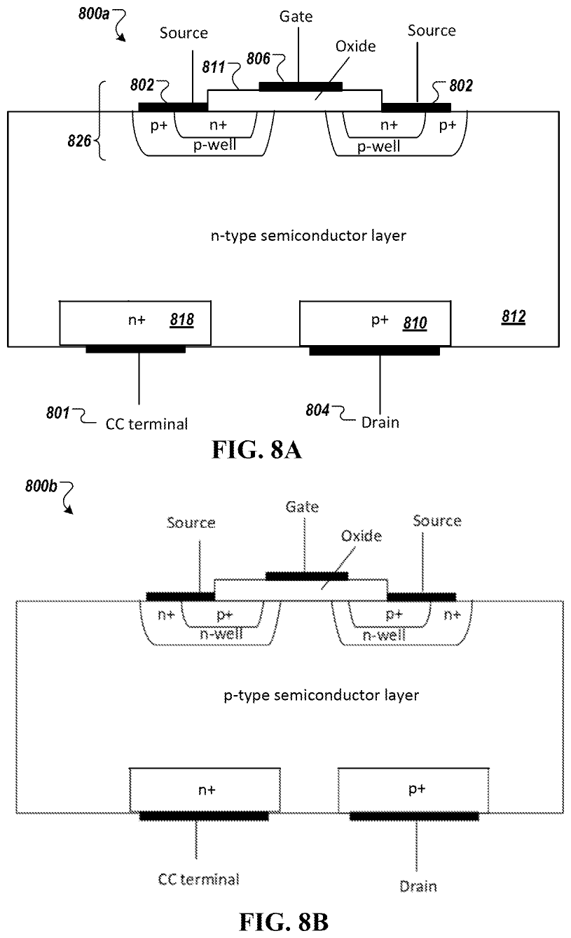

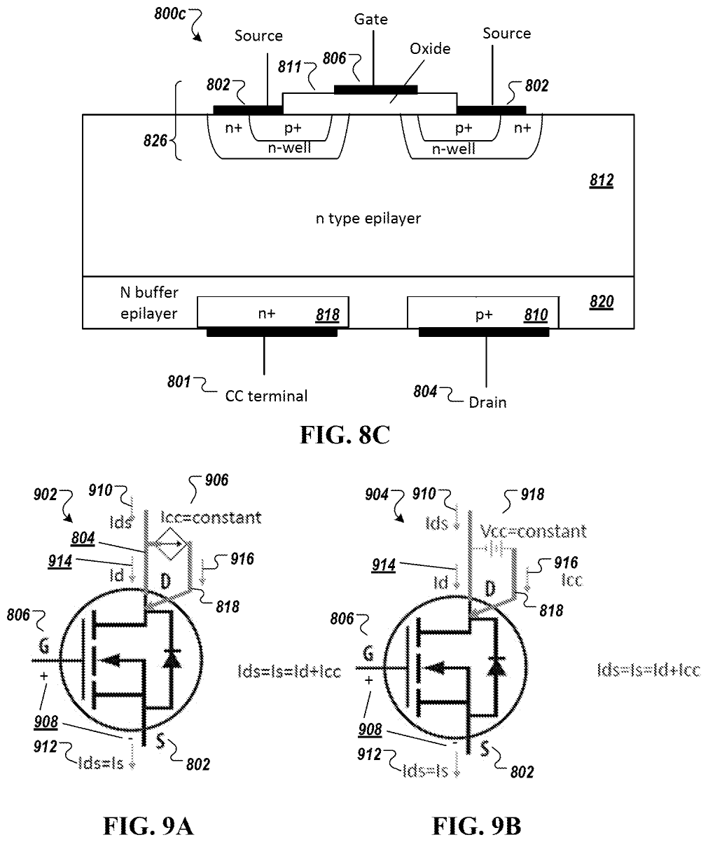

FIG. 8A shows an example implementation of the CC-MOSFET 800a of FIG. 1A as an N− type device. FIG. 8B shows example implementations of the CC-MOSFET 800b of FIG. 1A as a P− type device. The devices of FIGS. 8A and 8B can be fabricated with an N− buffer layer, as alternatively shown in FIG. 8C. In the example of FIGS. 8A and 8B, the CC-MOSFET devices 800a, 800b are a four-terminal power semiconductor device that can be made of Si, SiC, GaN, or other materials; the example shows an N− type semiconductor layer.

In FIG. 8A, the N+ doped region 810 comprising the drain includes an N+ type doped material formed in an N− type material 812, and the conductivity-controlled region 818 has a P+ type doped material region. The drain terminal 804 can be formed over drain region 810. In FIG. 20B, the P+ doped region comprising the drain includes a P+ type doped material formed in a P− type material, and the conductivity-controlled has an N+ type doped material region.

In the example of FIG. 8A, the top structure 826 of the CCBT is the same as a conventional MOSFET. The top structure 826 may include an N+ type doped material region fabricated over a p-well that is connected to a source terminal 802. An oxide layer 811 may be fabricated over the bulk epilayer 212 and across the N+ type doped material region and the p-well structure to which the gate terminal 806 may be formed. The CC-MOSFET 800a includes an additional conductivity-controlled device region 818 comprising a P+ layer that is added to the bottom of the device in proximity to the drain region 810 comprising an N+ layer. The conductivity-controlled device region 818 is connected to an additional conductivity-controlled contact 801 (shown as “CC Terminal” 801).

The CC-MOSFET 800a of FIGS. 8A and 8B can be fabricated using conventional MOSFET processing operations with an additional step to form the p+ CC terminal region 818. FIG. 8C shows an N− type CC-MOSFET 800c configured with an N− buffer layer 820. The inclusion of an N− buffer layer can improve the breakdown voltage of CCBT. N buffer doping 820 can be higher than N− layer 812 but lower than N+ 818.

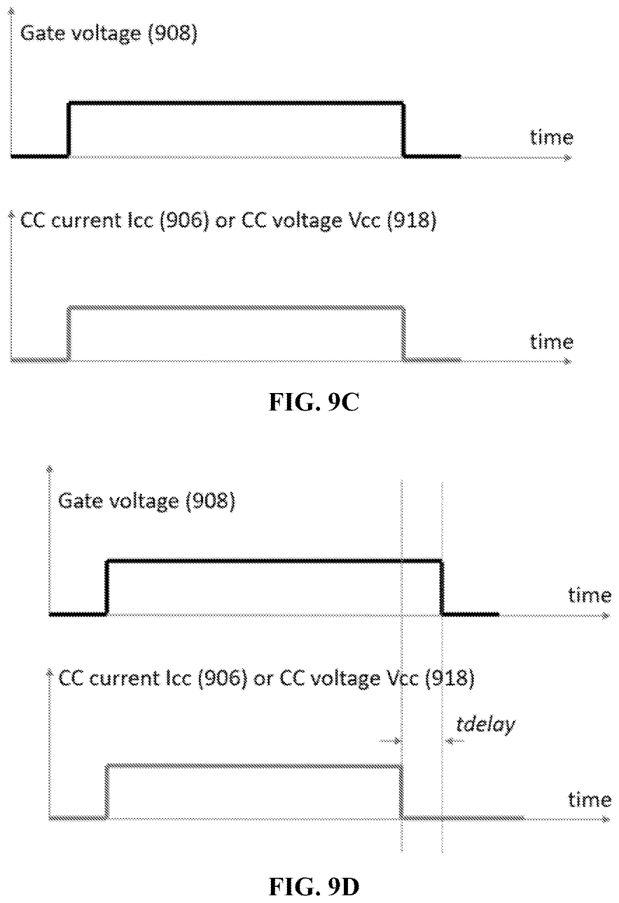

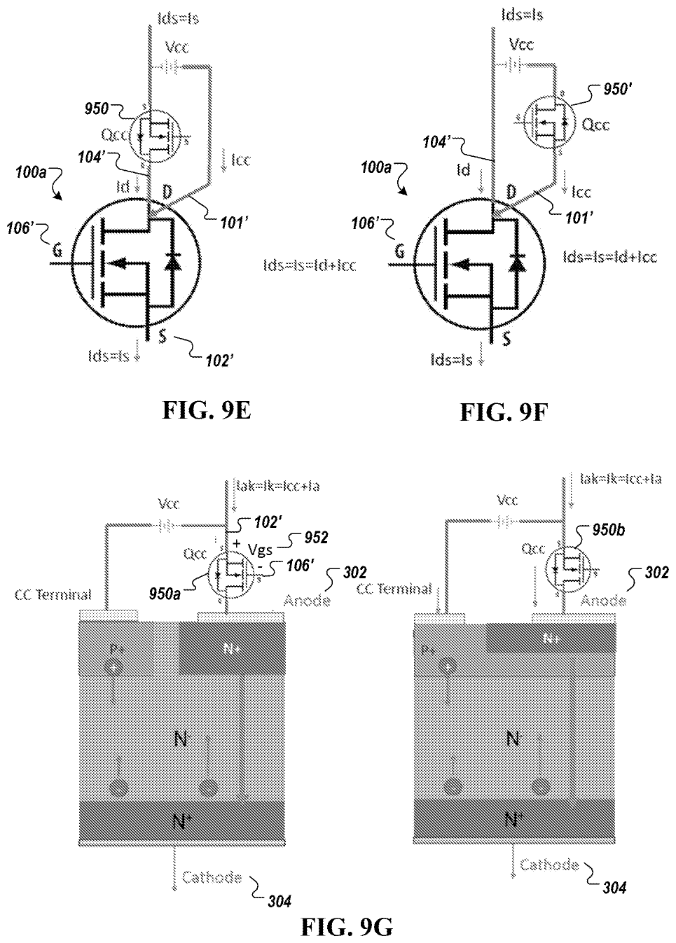

In the example of the CCBT devices of FIGS. 8A-8C, the CC-MOSFET 800a, 800b, 800c (and other CCBT devices described herein) can be actuated by the application of a constant current to the conductivity-controlled terminal 818 or a constant voltage to the conductivity-controlled terminal 818. FIGS. 9A and 9B show two example active-mode operations, via current control (for a device 902) and voltage control (for a device 904), respectively, of the CC-MOSFET devices 800a of FIG. 8A. FIGS. 9C and 9D show example timing diagrams of the active-mode operations. While shown for an N− type device, similar active-mode circuitry may be used for P− type devices. Also, while shown only for CC-MOSFET, similar active-mode circuitry may be used for other CCBT devices.

As shown in FIG. 9A (current-based control), to turn on the CC-MOSFET switch 902, a constant current bias 906 (shown as “Icc=constant” 906) can be applied to the CC terminal 818 (or 118, 218, 318, 418, etc.) at the same time a positive gate voltage 908 is applied to the gate terminal 806 and the source terminal 802 in the G-S terminals. To turn off the CC-MOSFET switch 902, the constant current bias 906, Icc, can be removed or kept on, i.e., Icc=constant current bias 906 is removed or kept on, while a zero or negative gate voltage 908 is applied to gate-source (G-S) terminals (806, 802). FIGS. 9C and 9D show timing diagrams for the operation of the gate voltage 908 and the terminal control signals Icc (906)

During operations, the current flow 910 through the device 902, as the output current 912 at the source terminal 802, can be determined as the input current 914 of the drain terminal 804 and the input current 916 of the CC terminal 818, i.e., Ids=Is=Id+Icc. The conductivity control gain, Beta=Id/Icc, can be defined as the ratio between the current 914 of the drain terminal 804 to the CC current 916 of the CC terminal 818. A higher gain would be preferred. The output 912 of the device 902, Ids, can be calculated as Ids=(1+beta)*Icc. The conductivity-controlled “on” resistance, R_{ds-on}, can be calculated as R_{ds-on}=Vds/Ids.

In FIG. 9B, device 904 (voltage-based control), to turn on the CC-MOSFET switch, a constant voltage 918 (shown as “Vcc=constant” 918) can be applied between the CC terminal 818 and the drain terminal 804 (also referred to collectively as the “CC-D” terminals (818, 804) as a positive gate voltage 908 is applied across the gate terminal 806 and the source terminal 802 (the “G-S” terminals (806, 802)). To turn off the CC-MOSFET switch 904, the constant voltage 918, Vcc, can be removed or kept on, i.e., Vcc=constant voltage is removed or kept on, while a zero or negative gate voltage 908 is applied to the gate-source (G-S) terminals (806, 802).

Example CC terminal control signals Icc (906) or Vcc (918) and their relationship with the gate signal (908) are shown in FIGS. 9E and 9F. In this case, these two signals are synchronized (e.g., as shown in FIG. 9C). Other types of controls can be performed to improve the performance of the CCBT devices. For example, FIG. 9G can be used to improve the switching performance of the CCBT devices. A time delay tdelay exists between the CC terminal control signals Icc (906) or Vcc (918) and the gate signal Vg (908) (see FIG. 9D). The tdelay can be optimized for a given application. Although FIGS. 9E, 9F, and FIG. 9G are shown for a CC-MOSFET device; it can also be applied to the 4 terminal CC-BJT device. In this case, the gate voltage (908) should be the base current of the CC-BJT.

### CCBT Drive Circuit

FIGS. 9E and 9F each show an example CCBT drive circuit 950, 950′ coupled to an example CCBT device to drive the CCBT device. The CCBT drive circuit 950 or 950′ can be integrated into the CCBT circuit on the same die and effectively reduces the number of terminals of the CCBT devices. In other embodiments, the driver circuit can be externally coupled to the CCBT device.

Though shown for the CC-MOSFET device (e.g., 100a), the CCBT drive circuit 950 can be integrated to other CCBT devices described herein (e.g., 100a, 100b, 100c, 100d, 200a, 200b, 300a, 300b, 400, 800a, 800b, 800c, 1000a, 1000b, 2000a, 2000b, 3000a, 3000b, etc.), including the CC-BJT, CC-rectifier, bidirectional CCBT.

In the example of FIG. 9E, the driver circuit 950 comprises an N channel MOSFET switch “Qcc” that is coupled to the drain terminal 104′ of a CC-MOSFET device. To turn on the driver circuit Qcc (950) a voltage can be applied to the gate terminal of the driver circuit 950, which would turn on the driver circuit Qcc 950 to apply a constant voltage Vcc to the CC terminal 101′. The Qcc turn-off gating signal could be synchronized with the CCBT main gate signal VGS.

In the example of FIG. 9F, the driver circuit 950′ comprises an N channel MOSFET switch “Qcc” that is coupled to the drain terminal 104′ of a CC-MOSFET device. To turn on the driver circuit Qcc (950) a voltage can be applied to the gate terminal 406′ of the driver circuit 950, which would turn on the driver circuit Qcc 950 to apply a constant voltage Vcc to the CC terminal 101′. The Qcc turn-off gating signal could be synchronized with the CCBT main gate signal VGS.

As noted, this drive circuit can be applied to all described CCBT devices. For a P− type CC-MOSFET, a P-channel MOSFET switch can be connected to the drain.

FIG. 9G shows the driver circuit 950 (shown as 950a, 950b) operatively coupled or fabricated onto a CC-rectifier (CCR) of FIGS. 3A, 3B. In the forward conduction mode of the CCR, the CCBT driver circuit Qcc 950a is turned on by application of the appropriate Vgs voltage 952 to the gate and source terminals (106′ and 102′). In reverse blocking mode, the Qcc 950a should be turned off. The driver circuit Qcc resistance could be selected to be small, e.g., less than 0.1V voltage drop at a rated current. Qcc breakdown voltage can be determined by the P+ and N+ structure design of the device 950a (or 950b, etc.).

### Example: 2—Fabricated CC-BJT

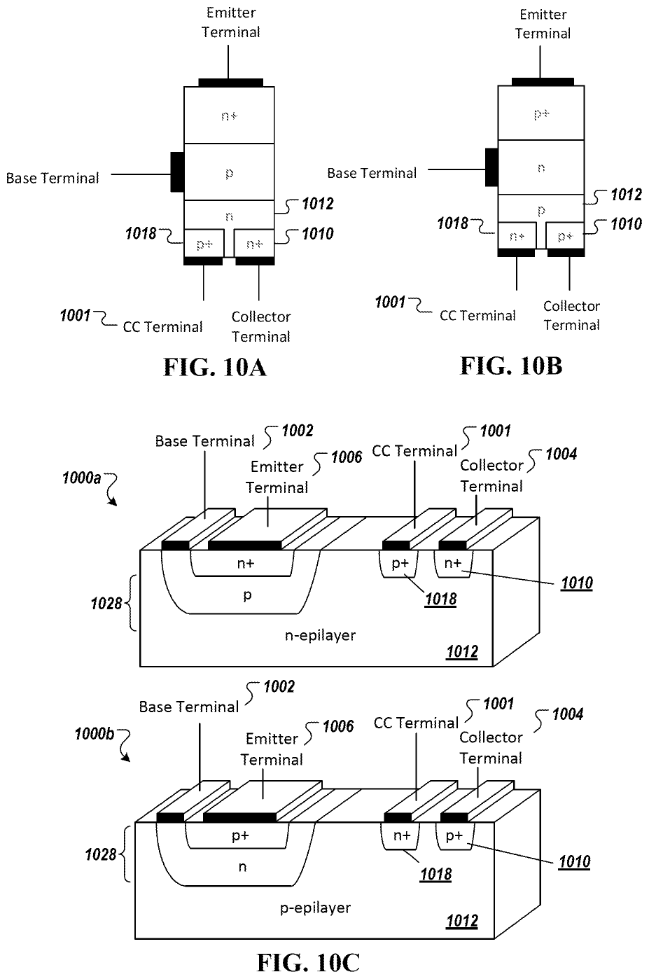

FIG. 10A shows an example implementation of a conductivity-controlled bipolar junction transistor (CC-BJT) device 1000a of FIG. 2A as an N− type device. FIGS. 10B shows example implementations of the CC-MOSFET 1000b of FIG. 2A as a P− type device. In the example of FIGS. 10A and 10B, the CC-BJT device 1000a, 1000b are each a four-terminal power semiconductor device that can be made of Si, SiC, GaN, or other materials.

The top structure of the 4-terminal CC-BJT (FIG. 10C) can be made the same as a conventional BJT. The 4-terminal CC-BJT 100a includes an additional conductivity-controlled device region 1018 comprising a P+ layer that is added to the bottom of the device in proximity to the collector region 1010 comprising an N+ layer. The conductivity-controlled device region 1018 is connected to an additional conductivity-controlled contact 1001 (shown as “CC Terminal” 1001).

FIG. 10A shows an example implementation of the CC-BJT 200a of FIG. 2A as an N− type device. FIG. 10B shows example implementations of the CC-BJT of FIG. 2 as a P− type device.

In FIG. 10A, the N+ doped region 1010 comprising the collector includes an N+ type doped material formed in an N− type bulk material 1012, and the conductivity-controlled region 1018 has a P+ type doped material region. In FIG. 10B, the P+ doped region 1010 comprising the collector includes a P+ type doped material formed in a P− type material 1012, and the conductivity-controlled region 1018 has an N+ type doped material region. FIG. 10C shows an example fabricated device 1000a and 1000b of the diagrams of FIGS. 10A and 10B.

The CC-BJT devices 1000a, 1000b form the conductivity-controlled region and structure between the first semiconductor region 1010 and the second semiconductor region 1012 that can modulate the controllable resistance for the device 1000 when energized by the third semiconductor region 1018 via the conductivity-controlled terminal 1001. The third semiconductor region 1018 can be fabricated with a third doping polarity material (e.g., a P+ material in FIG. 10A and an N+ material in FIG. 10B) that is opposite in doping polarity material to the first doping polarity material 1010. The N− device for a CC-BJT device 1000a includes an N+ and Pbase structure 1028 for the emitter terminal region (connected to emitter terminal 1006).

FIG. 10C shows a configuration of the power semiconductor CC-BJT device 200. FIG. 2B shows the same device 200 of FIG. 2A, which can include additional structures, e.g., a buffer layer 220 (shown in the example of an N⁺-type device). A corresponding P− device (not shown) can be similarly fabricated with the conductivity control terminal 201 and the third semiconductor region 218. The P device for a CC-BJT device may include a P− bulk second semiconductor region (212), a P+ first semiconductor region (210), an N+ third semiconductor region (118), and a P+ and Pbase structure for the emitter terminal region.

FIG. 10D shows an example operation of the driving circuit 1050 for the CC-BJT device 1000a, 1000b. FIG. 10D shows the driving circuit 1050 coupled to or fabricated with the CC-BJT device 200a, 200b of FIGS. 2A, 2B.

In the example of FIG. 10D, the CCBT switch 1000 is actuated by the application of a constant current or constant voltage to the collector terminal 1004 and the conductivity-controlled terminal 1018. To turn on the CC-MOSFET switch 1000a, 1000b, a constant current bias or voltage can be applied to the CC terminal 1018, as a positive base voltage is applied between the base and emitter (B-E) terminals 1002, 1006. To turn off the CC-BJT switch 1000a, 1000b, the constant current bias, I_{cc}, or voltage, V_{cc}, can be removed or kept on, i.e., Icc=constant current bias is removed or kept on, while a zero or the negative base voltage is applied to the base and emitter (B-E) terminals 1002, 1006.

During operations, the current flowing through the device, I_{ce}, (1000a, 1000b) can be determined as the input current of the collector terminal 1004 and the input current of the CC terminal 1001, i.e., I_{ce}=I_{c}+I_{cc}. The output current of the device (1000a, 1000b), Ie, can be determined as the input current of the collector terminal 1004, the current of the base terminal 1002, and the input current of the CC terminal 10001, i.e., Iₑ=I_{c}+I_{CC}+I_{b}. The conductivity control gain, Beta=Ic/Icc, can be defined as the ratio between the input current of the collector to the input current of the conductivity-controlled terminal in which the higher ratio is preferred. The conductivity-controlled “on” resistance, R_{ds-on}, can be calculated as R_{ds-on}=V_{ce}/I_{ce}.

While the examples shown in FIG. 10C is shown fabricated on a single surface, as noted above, the CCBT devices 200a, 200b can be fabricated on both sides (opposite surfaces) of a semiconductor device. The CCBT devices can also be readily fabricated on a single surface, as shown in FIG. 10C.

### Experimental Results and Examples

A study was conducted using simulations as a proof-of-concept validation of the CCBT device, including that of a CC-rectifier device and a CC-MOSFET device.

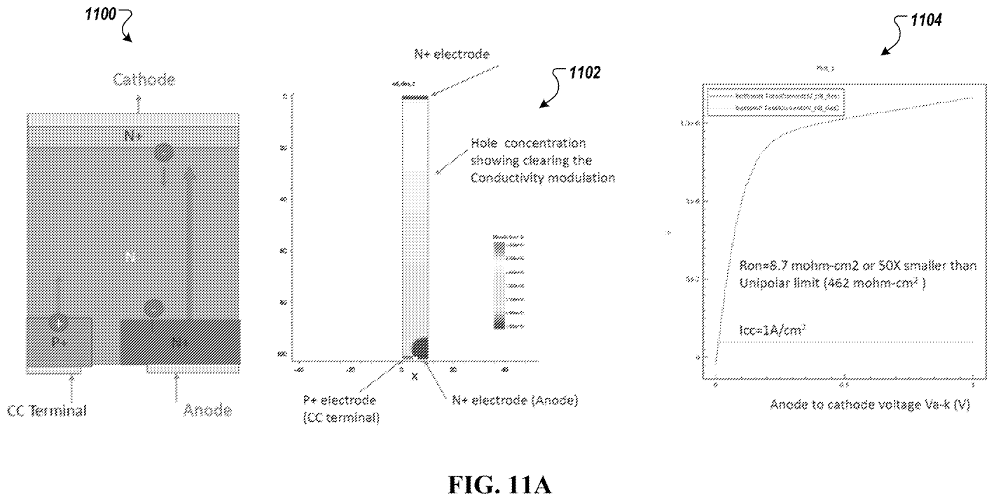

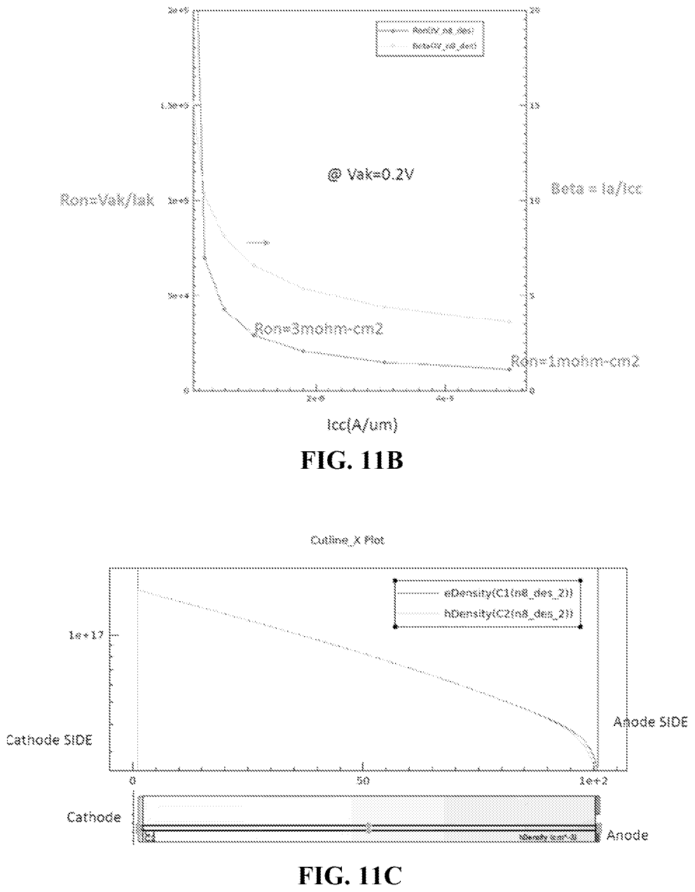

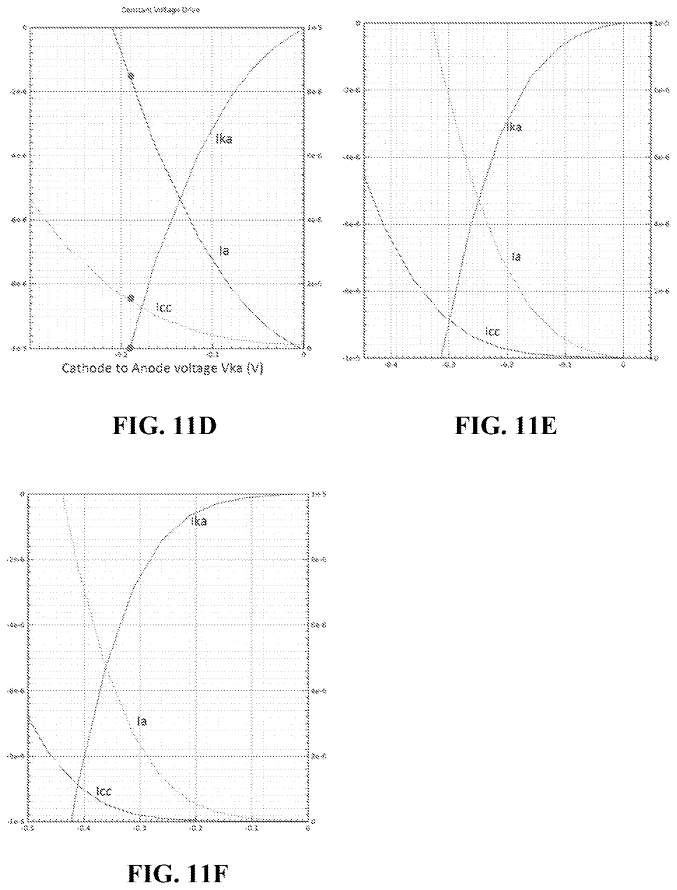

CC-Rectifier Simulation. FIG. 11A, diagram 1100 shows one of the simulated CC-resistor (CCR) structures used in a constant current drive simulation. Plot 1102 and plot 1104 show the results of the simulation. For the simulation, the CCR structure (of diagram 1100) is configured as a 1200V CCBT device and was simulated comprising cell width=10 μm, thickness=100 μm, N−=1e¹⁴, I_{cc}=1 A per cm². Plot 1102 shows the profile of the CCBT device in diagram 1100 in its actual scale.

FIG. 11B is a diagram showing the Ron characteristics of the CCBT device of diagram 1100.

FIG. 11C is a diagram showing the controlled conductivity profile of the CCBT device of diagram 1100 in terms of its electron and hole density. The simulation (of FIG. 11C) was performed with Vds=0.2V, Icc=50 A per cm². Indeed, FIG. 11C shows that the conductivity was improved by 1000× times (compared to that of a background doping of 1e14).

FIG. 11D shows the operation of the CCBT device with a constant voltage drive. The simulation used a cell width=10 μm. For the simulation, Vcc (constant voltage)=0.7V, Vak=0.19V @ Jak=100 A per cm², Rds-on=1.9 mohm-cm², and Beta=Ia/ICC=8.4/1.6=5.25. So, the total loss for the CCBT device can be calculated as Iₐₖ at 100 A=0.7V*16+0.2V*100=31 W.

FIG. 11E shows another simulation of the CCBT device with a constant voltage drive. For the simulation, Vcc (constant voltage)=0.6V, Vak=0.31V @ 100 A, R_{ds-on}=3.1 mohm-cm², and Vcc loss=0.6V*12 A. So, the total loss is 38 W with Beta=8/1.2-6.5.

FIG. 11F shows the operation of the CCBT device with a constant voltage drive. The simulation used a cell width=10 μm. For the simulation, Vcc (constant voltage)=0.5V, Vak=0.42V @ 100 A, R_{ds-on}=4.2 mohm-cm², and Vcc loss=0.5V*13 A. So, the total loss=42+6.5=48.5 W with Beta=7/1=7. It can be observed that the Icc is a function of Vak in the constant voltage drive operation.

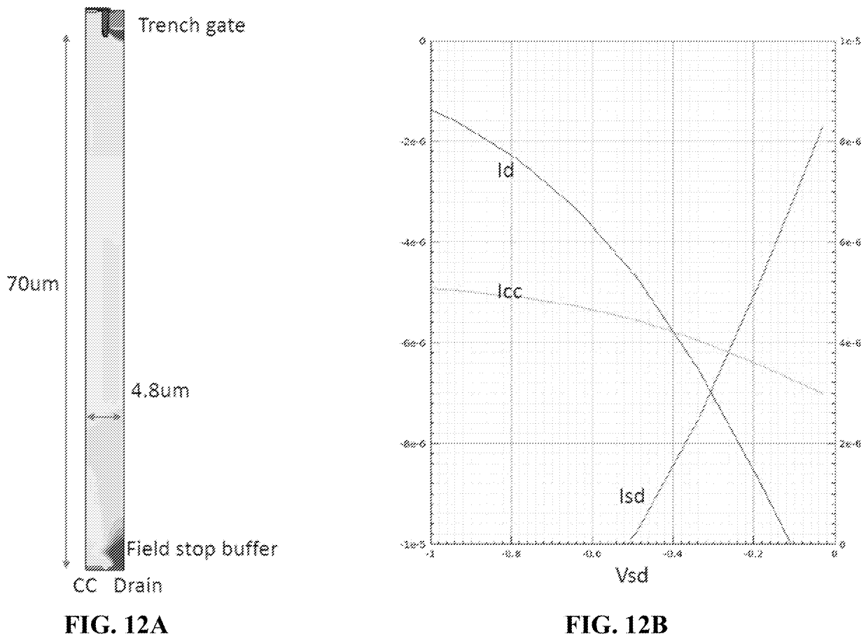

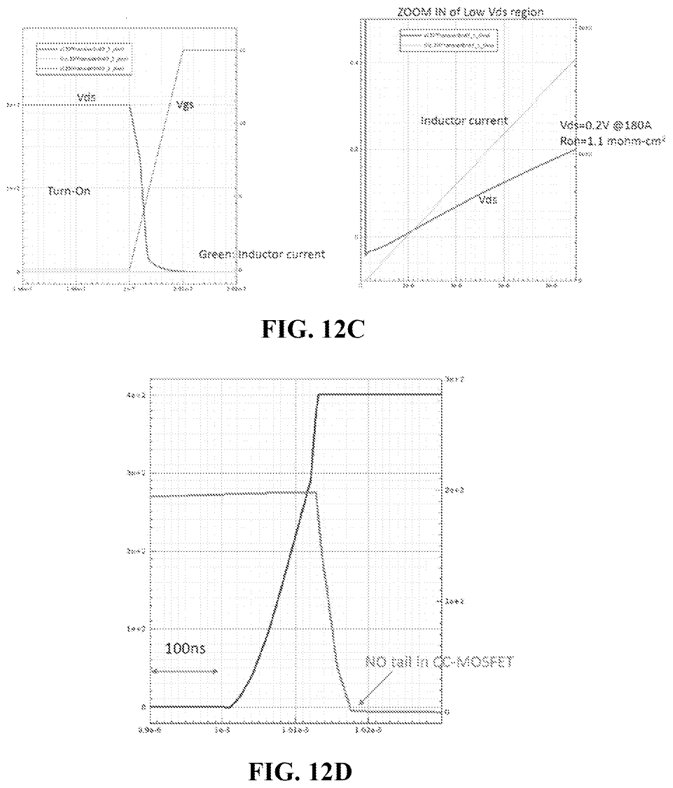

CC-MOSFET Simulation. FIGS. 12A and 12B show simulations of another device (CC-MOSFET) with a constant voltage drive. The simulation used a cell width=10 μm. From the simulation, Vcc=0.8V, Vgs==5V, Vds=0.5V @ 200 A per cm², R_{ds-on}=2.5 mohm-cm², Beta=Id/Icc @ 200 A=5/4.5=1.1 (buffer peak=1e18). So, the loss can be calculated as: Loss at 200 A=0.5V*200+0.8*100=180 W.

The operation appears to be equivalent to an “IGBT” voltage drop=180/200=0.9V. As a comparison, the simulation of an IGBT drop was conducted and determined to be 1.4V, which has a loss=1.4*200=280 W. The comparison shows a saving of a CCBT device to an IGBT of comparable configuration can be calculated as saving=100/280=35%.

Table 1 shows a summary of static loss improvement of the CCBT device over a comparable IGBT device. The loss reduction calculations (e.g., 35%, 51%, and 52.5%) may provide energy savings from conduction only. The Beta value could be removed to greater than 3(>3) by incorporating additional optimization techniques.

TABLE 1

| Field | Beta = | | | | Actual | |
|---|---|---|---|---|---|---|
| Stop | Id/Icc | | | Equivalent | IGBT | |
| Buffer | at Ids = | Vds at | Total Loss | IGBT | voltage | Loss |
| peak | 200 A/cm2 | 200 A | at 200 A | drop | drop | Reduction |
| 1e19 | <<1 | >>1 V, not | Does not | | 1.4 | N/A |
| | | able to | reach 200 A | | | |
| | | operate | | | | |
| | | at 200 A | | | | |
| 1e18 | 1.1 | 0.5 | 180 W | 0.9 V | 1.4 | 35% |
| 1e17 | 0.85 | 0.3 | 136 W | 0.68 V | 1.4 | 51% |
| 1e16 | 0.78 | 0.3 | 133 W | 0.665 V | 1.4 | 52.5% |

FIG. 12C shows a simulation of the CCBT inductive turn-on characteristics. In the simulation, Vcc=0.8V (on), Vgs=15V. FIG. 12D shows a simulation of the CCBT turn-off losses for a CC-MOSFET device. From the simulation, the turn-off loss, Eoff, can be calculated as: Eoff=0.5*400*200*160 ns=6.4 mJ or 32 uJ/A. Indeed, the simulation shows the CC-MOSFET device having very low dynamic turn-off losses, E_{off}.

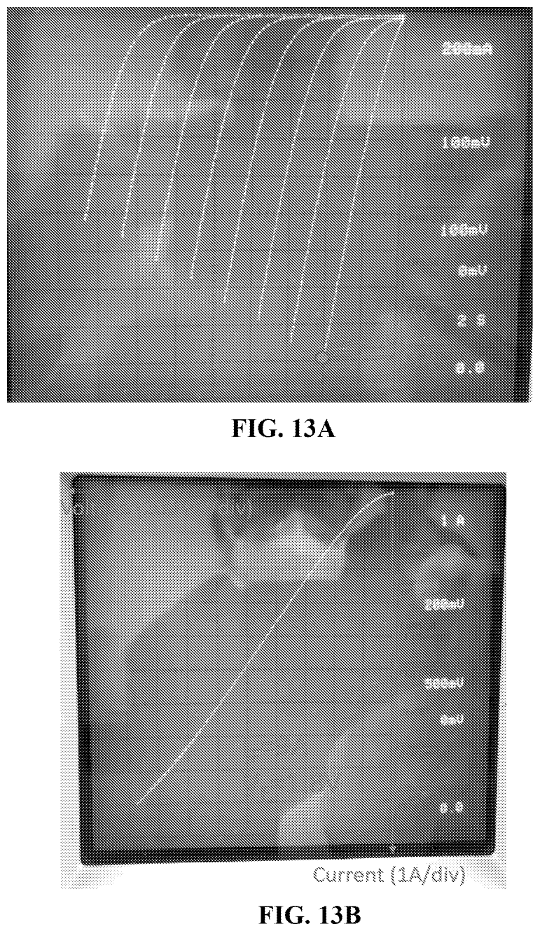

Fabricated device. FIGS. 13A and 13B show measured voltage-current (VI) curves as experimental results for a fabricated 1500V CC-Rectifier device and a fabricated 15000V SiC CC-BJT device, respectively. The fabricated device is a 1500V Si device having the structure shown in FIG. 3B. In FIG. 13A, the data shows a very low forward drop of 0.2V.

FIG. 13B shows a fabricated 15000V SiC CCBT device having the structure shown in FIG. 2B. In FIG. 13B, the data shows a very low forward drop of 1.8V. It is expected that the forward drop can be reduced to 0.3V through device optimization.

Each and every feature described herein, and each and every combination of two or more of such features, is included within the scope of the present invention, provided that the features included in such a combination are not mutually inconsistent.

Although example embodiments of the disclosed technology are explained in detail herein, it is to be understood that other embodiments are contemplated. Accordingly, it is not intended that the disclosed technology be limited in its scope to the details of construction and arrangement of components set forth in the following description or illustrated in the drawings. The disclosed technology is capable of other embodiments and of being practiced or carried out in various ways.

It must also be noted that, as used in the specification and the appended claims, the singular forms “a,” “an” and “the” include plural referents unless the context clearly dictates otherwise. Ranges may be expressed herein as from “about” or “approximately” one particular value and/or to “about” or “approximately” another particular value. When such a range is expressed, other exemplary embodiments include from the one particular value and/or to the other particular value.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including matters of logic with respect to arrangement of steps or operational flow; plain meaning derived from grammatical organization or punctuation; the number or type of embodiments described in the specification.

While the methods and systems have been described in connection with certain embodiments and specific examples, it is not intended that the scope be limited to the particular embodiments set forth, as the embodiments herein are intended in all respects to be illustrative rather than restrictive.

1. A power semiconductor device comprising:
one or more conductivity-controlled devices comprising one or more conductivity-controlled diodes, one or more conductivity-controlled transistors or thyristors, or one or more conductivity-controlled FET-based devices, wherein each of the one or more conductivity-controlled devices comprises
a set of terminals including at least a first terminal, a second terminal, and a conductivity-controlled terminal;
a first semiconductor region having a first doping polarity material that is coupled to the first terminal;
a second semiconductor region having a second doping polarity material (i) in contact with the first semiconductor region and (ii) is coupled to the second terminal, the first and second semiconductor regions being configured to generate an electric field opposite in direction to electron flow, or the same direction of hole flow, when a voltage is applied; and
a third semiconductor region having a third doping polarity material that is opposite in doping polarity material to a doped region comprising either one of the first doping polarity material or the second doping polarity material, the third semiconductor region being coupled to the conductivity-controlled terminal to generate, when energized, a second electric field that reduces the resistance of the first and second semiconductor regions.

2. The power semiconductor device of claim 1, wherein the one or more conductivity-controlled devices are configured as
a diode with a conductivity-controlled terminal,
a BJT with a conductivity-controlled terminal,
a BJT with a conductivity-controlled terminal acting as a base terminal
a MOSFET with a conductivity-controlled terminal, or
a thyristor with a conductivity-controlled terminal.

3. The power semiconductor device of claim 1, wherein the doped region comprising the either one of the first doping polarity material or the second doping polarity material includes an N+ type doped material, and wherein the third semiconductor region having the third doping polarity material includes a P+ type doped material.

4. The power semiconductor device of claim 1, wherein the doped region comprising the either one of the first doping polarity material or the second doping polarity material includes a P+ type doped material, and wherein the third semiconductor region having the third doping polarity material includes an N+ type doped material.

5. The power semiconductor device of claim 1,
wherein the second semiconductor region comprises an N type substrate that has an N+ type doped cathode region,
wherein the third semiconductor region comprises a P+ type doped conductivity-controlled region formed in the second semiconductor region, and
wherein the first semiconductor region comprises an N+ type doped anode region formed over the oppositely doped P+ type doped conductivity-controlled region of the third semiconductor region.

6. The power semiconductor device of claim 1,
wherein the second semiconductor region comprises a P type substrate that has a P+ type doped cathode region,
wherein the third semiconductor region comprises an N+ type doped conductivity-controlled region formed in the second semiconductor region, and
wherein the first semiconductor region comprises a P+ type doped anode region formed over the oppositely doped N+ type doped conductivity-controlled region of the third semiconductor region.

7. The power semiconductor device of claim 1,
wherein the second semiconductor region comprises an N type substrate,
wherein the third semiconductor region comprises (i) a first P+ type doped conductivity-controlled region formed in the second semiconductor region and (ii) a second P+ type doped conductivity-controlled region formed in the second semiconductor region, and
wherein the first semiconductor region comprises (i) a first N+ type doped cathode-anode region that is formed in the oppositely doped first P+ type doped conductivity-controlled region and (ii) a second N+ type doped cathode-anode region that is formed in the oppositely doped second P+ type doped conductivity-controlled region.

8. The power semiconductor device of claim 1,
wherein the second semiconductor region comprises a P type substrate,
wherein the third semiconductor region comprises (i) a first N+ type doped conductivity-controlled region formed in the second semiconductor region and (ii) a second N+ type doped conductivity-controlled region formed in the second semiconductor region, and
wherein the first semiconductor region comprises (i) a first P+ type doped cathode-anode region that is formed in the oppositely doped first N+ type doped conductivity-controlled region and (ii) a second P+ type doped cathode-anode region that is formed in the oppositely doped second N+ type doped conductivity-controlled region.

9. The power semiconductor device of claim 1,
wherein the second semiconductor region comprises an N type substrate that has an N+ type doped cathode region,
wherein the first semiconductor region comprises an N+ type doped anode region formed in the second semiconductor region; and
wherein the third semiconductor region comprises a P+ type doped conductivity-controlled region formed in the second semiconductor region that is oppositely doped and in proximity to the N+ type doped anode region of the first semiconductor region.

10. The power semiconductor device of claim 1,
wherein the second semiconductor region comprises a P type substrate that has a P+ type doped cathode region,
wherein the first semiconductor region comprises a P+ type doped anode region formed in the second semiconductor region; and
wherein the third semiconductor region comprises an N+ type doped conductivity-controlled region formed in the second semiconductor region that is oppositely doped and in proximity to the P+ type doped anode region of the first semiconductor region.

11. The power semiconductor device of claim 1, wherein the power semiconductor device comprises a conductivity-controlled bipolar-based device, a set of terminals comprising a base electrode as the first terminal, a collector electrode as the second terminal, an emitter electrode as a third terminal, and conductivity-controlled electrode as the conductivity-controlled terminal.

12. The power semiconductor device of claim 11,
wherein the second semiconductor region comprises an N type substrate that has an N+ type doped collector region,
wherein the first semiconductor region comprises a P+ type doped base region formed in the P type semiconductor region that is layered over the second semiconductor region, the P type semiconductor region having formed an N+ type doped emitter region and the P+ type doped base region; and
wherein the third semiconductor region comprises a P+ type doped conductivity-controlled region formed in the second semiconductor region that is oppositely doped and in proximity to the N+ type doped collector region of the second semiconductor region.

13. The power semiconductor device of claim 11,
wherein the second semiconductor region comprises a P type substrate that has a P+ type doped collector region,
wherein the first semiconductor region comprises an N+ type doped base region formed in the N type semiconductor region that is layered over the second semiconductor region, the N type semiconductor region having formed a P+ type doped emitter region and the N+ type doped base region; and
wherein the third semiconductor region comprises an N+ type doped conductivity-controlled region formed in the second semiconductor region that is oppositely doped and in proximity to the P+ type doped collector region of the second semiconductor region.

14. The power semiconductor device of claim 11,
wherein the second semiconductor region comprises a P type substrate that has an N+ type doped collector region that is formed in an N type semiconductor region that is layered over the second semiconductor region,
wherein the first semiconductor region comprises an N+ type doped emitter region formed over the P type substrate; and
wherein the third semiconductor region comprises a P+ type doped conductivity-controlled region formed in the N type semiconductor region and is oppositely doped and in proximity to the N+ type doped collector region

15. The power semiconductor device of claim 1, wherein the power semiconductor device comprises a conductivity-controlled metal oxide semiconductor field emitting transistor-based device, the set of terminals comprising a source electrode as the first terminal, a drain electrode as the second terminal, a gate electrode as a third terminal, and conductivity-controlled electrode as the conductivity-controlled terminal.

16. The power semiconductor device of claim 15,
wherein the second semiconductor region comprises an N type substrate that has an N+ type doped drain region,
wherein the first semiconductor region comprises a P+ type doped base region formed in the P type semiconductor region that is layered over the second semiconductor region, the P type semiconductor region having formed an N+ type source region and the P+ type doped source region, wherein the gate electrode is formed on an oxide layer that is formed over a portion of the P type semiconductor region and the N+ type emitter region of the P type semiconductor region; and
wherein the third semiconductor region comprises a P+ type doped conductivity-controlled region formed in the second semiconductor region that is oppositely doped and in proximity to the N+ type doped drain region of the second semiconductor region.

17. The power semiconductor device of claim 15,
wherein the second semiconductor region comprises a P type substrate that has a P+ type doped drain region,
wherein the first semiconductor region comprises an N+ type doped base region formed in the N type semiconductor region that is layered over the second semiconductor region, the N type semiconductor region having formed a P+ type source region and the N+ type doped source region, wherein the gate electrode is formed on an oxide layer formed over a portion of the N type semiconductor region and the P+ type emitter region of the P type semiconductor region; and
wherein the third semiconductor region comprises an N+ type doped conductivity-controlled region formed in the second semiconductor region that is oppositely doped and in proximity to the P+ type doped collector region of the second semiconductor region.

18. A power semiconductor device comprising:
a first semiconductor region having a first doping polarity material that is coupled to a first terminal;
a second semiconductor region coupled to a second terminal, the second semiconductor region having a second doping polarity material in contact with the first semiconductor region, wherein the first semiconductor region and second semiconductor region have an effective resistance to electron flow, or hole flow, that can be modulated by an electric field that is generated by another structure of the power semiconductor device; and
a third semiconductor region coupled to a third terminal, the third semiconductor region having a third doping polarity material that is opposite in doping polarity material to a doped region comprising either one of the first doping polarity material or the second doping polarity material, the third semiconductor region being coupled to the third terminal to generate, when energized, a second electric field that reduces the resistance of the first and second semiconductor regions.

19. The power semiconductor device of claim 18, further comprising:
a driver circuit that is coupled to the first terminal and the third terminal.

20. The power semiconductor device of claim 19, wherein the driver circuit provides a constant voltage between the first and third terminals, or a constant current between the first and third terminals, and wherein the polarity of the voltage or current is to introduce conductivity modulation.

21-32. (canceled)
